(19) United States
(12) Patent Application Publication
(10) Pub. No.: US 2026/0101724 A1
(43) Pub. Date: Apr. 9, 2026

(54) System and Method for Rapid Process Chamber Pressure Modulation Using an Array of Small Valves and Pumps

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/908,690

(22) Filed: Oct. 7, 2024

(51) Int. Cl. H01L 21/66; G05B 6/02; H01L 21/67

(52) U.S. Cl. CPC H10P 74/238; G05B 6/02; H10P 72/0402; H10P 72/0604

(57) ABSTRACT

The present disclosure relates to a system for semiconductor manufacturing, designed for rapid chamber pressure modulation through an array of small valves and pumps. The system incorporates micro shutters to achieve precise and rapid gas flow regulation. A system controller adjusts motor currents to compensate for nonuniformities resulting from incoming substrates and design constraints within the process system, thereby ensuring improved substrate uniformity during semiconductor manufacturing processes.

### FIELD OF THE INVENTION

The present invention relates to semiconductor manufacturing equipment, specifically to systems designed to modulate pressure within process chambers more rapidly during semiconductor fabrication processes.

### BACKGROUND OF THE INVENTION

In semiconductor manufacturing, achieving target chamber pressure quickly is critical, particularly in processes like atomic layer deposition (ALD) and atomic layer etching (ALE). Current systems generally rely on a large pump, typically positioned at the base of the process chamber, to evacuate reaction byproducts and maintain an environment conducive to chemical reactions. These systems also use a large valve to regulate the chamber pressure. However, the slow operation of this valve often results in delays when stabilizing chamber pressure. As semiconductor manufacturing processes demand faster chamber pressure modulation, a need arises for a system that accelerates this process.

### SUMMARY OF THE INVENTION

The following is a brief overview of various aspects of the invention, which are described in greater detail in the Detailed Description. This summary is not intended to limit the scope of the invention, nor does it highlight all features of the invention.

The present invention addresses the need for faster chamber pressure modulation by introducing a system that uses an array of small valves and pumps. This configuration significantly reduces the time required for a process chamber to reach its desired steady-state pressure. Unlike conventional systems that rely on a large pump and valve, the invention utilizes multiple small, fast-acting valves, also referred to as micro shutters, to regulate gas evacuation. These micro shutters are similar in function to camera shutters but have been adapted for this novel use.

Each micro shutter consists of one or more blades that control the flow of gases into the corresponding pumps. A motor-driven actuator, using a rotational-to-linear conversion mechanism, synchronizes the blade movements, optimizing gas evacuation and enabling rapid pressure adjustments. A system controller adjusts the motor currents to regulate the blade positions based on feedback from a manometer that monitors chamber pressure in real-time. The controller uses a proportional-integral-derivative (PID) control to ensure fast and stable pressure regulation.

Additionally, the system can correct for substrate nonuniformities caused by earlier processing steps or design limitations. In some embodiments, a uniformity engine assesses the necessary adjustments to counteract incoming substrate nonuniformity. The system controller then modulates the motor currents to vary the size of the apertures in the micro shutters, ensuring improved substrate uniformity during the process.

In summary, the invention provides a novel solution for rapid process chamber pressure modulation by integrating an array of small valves and pumps with an advanced control system.

### BRIEF DESCRIPTIONS OF DRAWINGS

The embodiments of the invention will be more fully understood by reference to the following descriptions, in conjunction with the accompanying drawings:

FIG. 1A: Schematic diagram of a process chamber featuring an array of small valves and pumps for rapid pressure modulation.

FIG. 1B: Top view of the array of micro shutters, functioning as fast-switching valves.

FIG. 2: Functional diagram showing the components and interactions of the valve and pump array in the process chamber.

FIG. 3: Flowchart outlining the process for modulating chamber pressure using the array of small valves and pumps.

FIG. 4: Flowchart showing a process for chamber pressure modulation with optimized substrate uniformity, where motor currents are adjusted for different valves.

### DETAILED DESCRIPTIONS

This section provides a detailed explanation of specific implementations of the present invention to ensure a clear understanding. While certain details are discussed for clarity, various modifications and adaptations that fall within the scope of the appended claims are possible. Established processes and components are only selectively described to emphasize the novel features of the invention.

### Definitions

For the purposes of this description, the following terms are defined as follows:
Process Chamber: A controlled environment where semiconductor manufacturing processes, such as etching or deposition, are carried out.
Chuck: A structure within the process chamber that holds the substrate (e.g., a silicon wafer) during processing. It may be a vacuum chuck or an electrostatic chuck.
Mass Flow Controller (MFC): A device that regulates the flow rate of gases into the process chamber.
Vacuum Valve: A valve that controls the removal of gases from the process chamber through positioning a movable part, typically used with a vacuum pump to maintain or adjust the chamber pressure.
Gas Distribution Unit: A component that introduces processing gases into the process chamber. The unit can be configured as a showerhead or injector, depending on the design.
Gas Conduction Aperture: The opening controlled by the micro shutter, which determines the rate of gas flow through the chamber pressure control system.
Manometer: A pressure measurement device used to monitor the pressure inside the process chamber.
Steady-State Pressure: The target pressure defined by the process recipe, where the chamber operates under stable conditions.
Micro Shutter: A device with one or more movable blades that control the gas conduction aperture, regulating gas flow similarly to a camera shutter mechanism.
Blades (of the Micro Shutter): Movable parts that adjust the size of the gas conduction aperture to control gas flow and chamber pressure.
Shutter Actuator: A mechanism that drives the movement of the blades within the micro shutter, typically powered by a motor.
Rotation-to-Linear Conversion Mechanism: A mechanism that converts the rotational movement of a motor into linear movement, allowing for precise control of the shutter actuator.
PID Control (Proportional-Integral-Derivative Control): A control algorithm that adjusts system parameters (e.g., motor currents) to reach the desired setpoint, based on current and past deviations in chamber pressure.
System Controller: A control system responsible for managing the operations of the chamber, including motor currents, actuator movements, and gas flow adjustments, based on feedback from the manometer.
Process Recipe: A predefined set of operational instructions (e.g., gas flow, pressure, and timing) that governs the semiconductor manufacturing process.
Substrate: The material, typically a silicon wafer, that undergoes processing inside the chamber.
Array of Valves and Pumps: A configuration of multiple small valves and pumps used in the chamber to rapidly regulate gas flow and chamber pressure.
Motor Currents: Electrical currents supplied to the motors controlling the micro shutters, used to adjust the blade positions and modulate gas flow.
Uniformity Engine: A subsystem or software module within the system controller designed to compensate for nonuniformities in the substrate or process design, adjusting motor currents to enhance substrate uniformity.
Nonuniformity: Variations in the substrate or process conditions that can affect the uniformity of semiconductor processing, which may be addressed through the system controller.

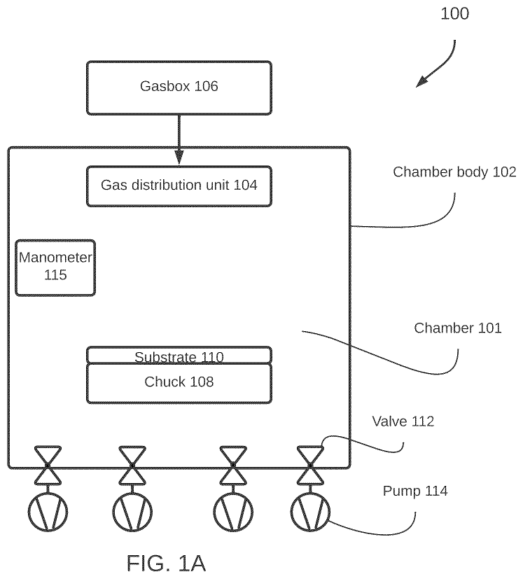

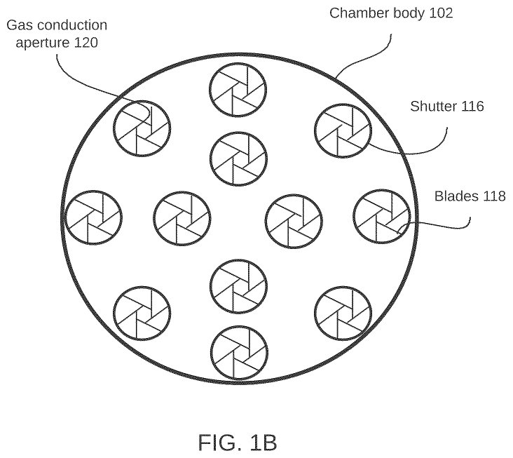

FIG. 1A depicts a schematic of an embodiment 100, showing a process chamber 101. The chamber body 102 encloses a vacuum environment suitable for semiconductor processing. A gas distribution unit 104 is connected to a gasbox 106 via multiple mass flow controllers (MFCs) (not shown). In one implementation, the gas distribution unit 104 functions as a showerhead; in another, it acts as an injector. The chamber 101 also includes a chuck 108, which can be a vacuum chuck or an electrostatic chuck, to support the substrate 110 during processing. Substrates may vary in size, typically being silicon wafers.

In conventional process chambers, a large pump located at the base of the chamber aids in the removal of reaction byproducts and gases through an exhaust line. A large vacuum valve, used with the pump, maintains consistent pressure for the chemical reactions within the chamber 101. The manometer 115 monitors the chamber pressure and adjusts the valve if any deviations are detected, typically requiring several hundred milliseconds for corrections.

Achieving the chamber pressure specified by the process recipe with a large pump, a large valve, and a PID control often takes several tens to hundreds of milliseconds. However, advanced techniques like ALD and ALE demand faster pressure modulation.

Embodiment 100 introduces an innovative approach, using an array of small valves 112 and pumps 114 to accelerate chamber pressure stabilization. This also provides finer control for improving substrate uniformity.

FIG. 1B shows a top view of the array of small valves incorporating micro shutters 116. While this embodiment features twelve micro shutters, the number can vary. These micro shutters, similar to camera shutters, act as fast-switching valves paired with pumps. Each micro shutter consists of one or more blades 118 that adjust gas flow rates into the pump by altering their collective positions, thus controlling the gas conduction aperture 120. The blade movements are coordinated by an actuator, driven by a motor via a rotation-to-linear conversion mechanism.

The use of smaller valves and pumps makes fabrication more practical. Small pumps can be produced using additive manufacturing or 3D printing techniques, and the micro shutters, inspired by camera technology, offer an efficient, cost-effective solution for integrating these valves and pumps into the system.

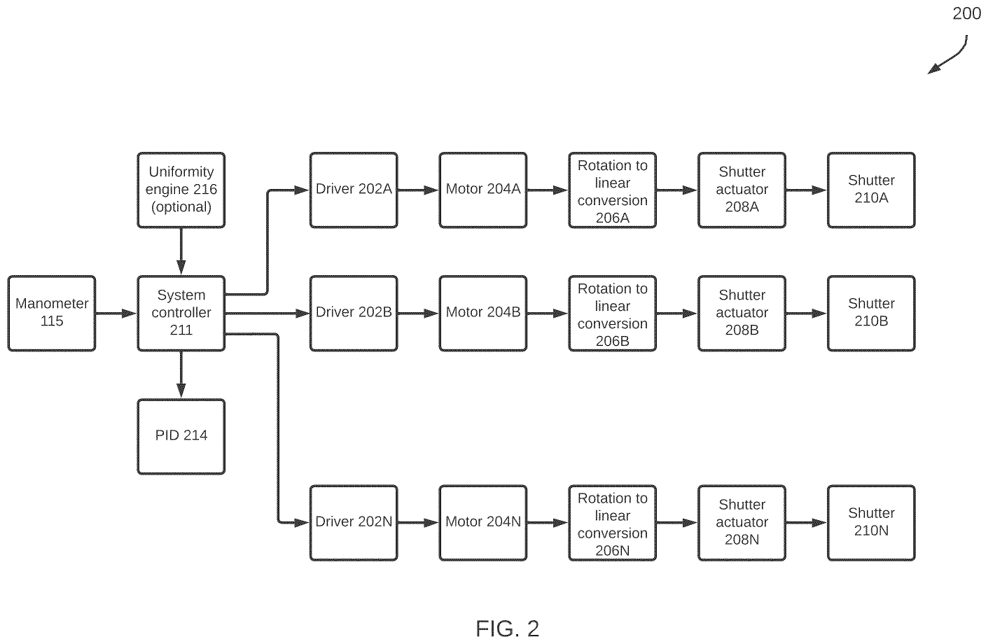

FIG. 2 illustrates a functional diagram showing the interaction of components within the small valve and pump array for process chamber 101. The system 200 consists of an array of small valves and pumps labeled from “A” to “N.” Each unit includes a driver 202 (A-N) powering a motor 204 (A-N), connected through a rotational-to-linear conversion mechanism 206 (A-N). For instance, in the case of valve “A,” the driver 202A regulates the speed of motor 204A by adjusting the current supplied to it, which in turn affects the rotation-to-linear conversion mechanism 206A, the shutter actuator 208A, and the size of the shutter aperture 210A.

A system controller 211 manages the distribution of current to motors 204A through driver 202A. The stability of chamber pressure depends on two key factors: (1) the gas flow rate from the gas distribution unit 104 and (2) the gas withdrawal rate, which is influenced by the aperture size of the shutter and the capacity of the pump. The chamber pressure is measured by a manometer 115 at set intervals. If a deviation from the target pressure is detected, the system controller 211 activates a proportional-integral-derivative (PID) control 214 to correct the situation.

The small valve and pump array offers an innovative approach to enhancing the uniformity of substrate 110. In conventional semiconductor manufacturing, substrates may exhibit nonuniformities due to process variations accumulated over multiple stages. Correcting these nonuniformities in subsequent processing steps is often desirable. An optional uniformity engine 216 is employed to determine the level of nonuniformity needed for the current process. The system controller 211 receives this input and adjusts the current to different motors, improving the uniformity of the substrate after processing.

In some embodiments, the uniformity engine 216 includes a software module that may incorporate digital twins of the process system and associated processes. The uniformity engine 216 can utilize these digital twins to simulate and calculate the necessary motor currents to compensate for substrate nonuniformities, which may result from one or more prior processing steps. In other embodiments, the uniformity engine 216 can simulate nonuniformities arising from design constraints of the process system 100 and determine solutions to correct these design-related variations by adjusting the motor currents. Integrated within the system controller 211, the uniformity engine 216 may also include firmware and hardware components to accelerate the calculation and application of the motor currents.

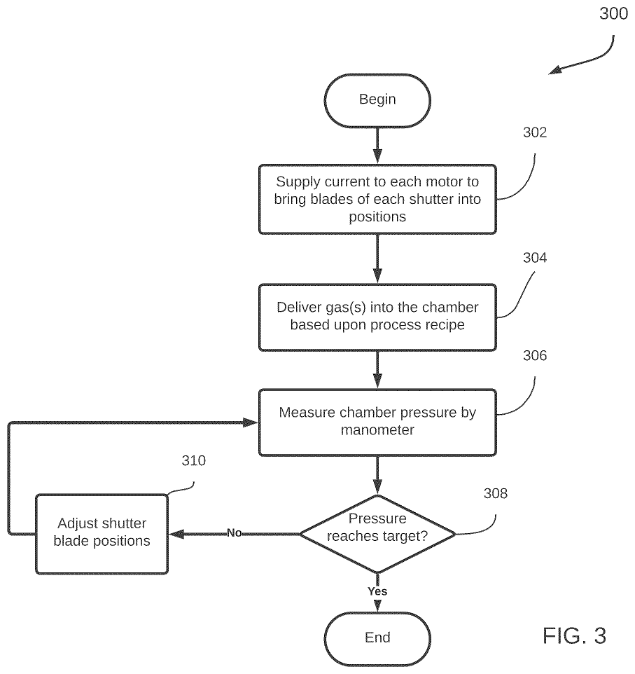

FIG. 3 provides a flowchart for process 300, detailing the chamber pressure modulation using the small valve and pump array. In step 302, each motor 204 is supplied with a current to appropriately position the shutter 210 blades. Process gases are introduced into the chamber through the gas distribution unit 104 in step 304. The manometer 115 measures the chamber pressure in step 306, and if the measured pressure deviates from the target in step 308, the system controller 211 adjusts the motor currents iteratively in step 310, utilizing the PID control 214 to reach the desired pressure.

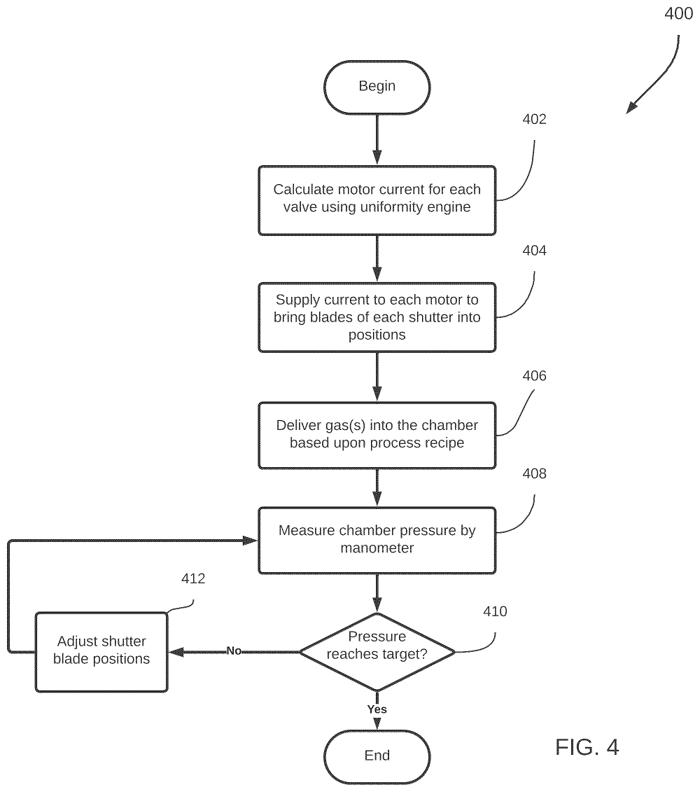

FIG. 4 presents process 400, which focuses on optimizing substrate uniformity by applying different motor currents to various valves. The process begins in step 402, where the uniformity engine 216 provides input to the system controller 211 to calculate the appropriate current for each motor 204. In step 404, the calculated currents are applied to the motors 204, aligning the shutter blades 210. Process gases are introduced into the chamber in step 406, and the chamber pressure is measured by the manometer 115 in step 408. If there is a deviation from the target pressure in step 410, the system controller 211 adjusts the motor currents iteratively in step 412, using the PID control 214 to expedite the process.

1. A process chamber for semiconductor manufacturing, comprising:
a chamber body configured to maintain a vacuum environment;
a gas distribution unit situated within the chamber body for introducing gases;
an array of valves, wherein each valve comprises a micro shutter having one or more blades, and wherein the collective positions of the blades control the gas withdrawal rate into associated pumps; and
a system controller configured to adjust currents supplied to motors connected to the micro shutters for modulating positions of the blades based on a chamber pressure measured by a manometer, and comparing to the target value, stipulated from a process recipe.

2. The chamber of claim 1, wherein the blade's positions are determined by a shutter actuator, the actuator being coupled to a motor through a rotation-to-linear conversion mechanism.

3. The chamber of claim 2, wherein the collective positions of the blades define the size of an aperture of the shutter, which in turn determines the gas withdrawal speed into the pump.

4. The chamber of claim 1, wherein the system controller employs a proportional-integral derivative (PID) control to achieve the steady state chamber pressure.

5. The chamber of claim 1, wherein the system controller further comprising a uniformity engine configured to gauge the required nonuniformity for the current process, the system controller adjusting motor currents based on the input from the uniformity engine to optimize substrate uniformity.

6. The chamber of claim 1, wherein the pumps associated with the micro shutters are manufactured using additive manufacturing technologies or three-dimensional printing techniques.

7. The chamber of claim 1, wherein each pump and valve are integrated as a single piece.

8. A method for modulating chamber pressure in a semiconductor manufacturing process chamber, the method comprising:
maintaining a vacuum environment within a chamber body;
introducing processing gases via a gas distribution unit;
controlling gas withdrawal rate by modulating positions of one or more blades of micro shutters in an array of valves;
adjusting current supplied to motors coupled to said micro shutters based on chamber pressures measured by a manometer and comparing the measured pressure to the target value; and
using a system controller to adjust the blade positions of the micro shutters until the measured pressure matches the targeted value.

9. The method of claim 8, further comprising synchronizing the positions of the blades using an actuator coupled to a motor through a rotational-to-linear conversion mechanism.

10. The method of claim 8, further comprising the use of a PID control by the system controller to stabilize the chamber pressure.

11. The method of claim 8, further comprising determining a required nonuniformity for the current process using a uniformity engine, where the system controller adjusts motor currents based on input from the uniformity engine to achieve optimized substrate uniformity.

12. The method of claim 11, wherein the uniformity engine utilizes incoming substrate data.

13. A method for achieving uniform results across a substrate in a semiconductor manufacturing process chamber, the method comprising:
maintaining a vacuum environment within a chamber body;
providing a substrate onto a chuck within the chamber body;
introducing gases inside the chamber body via a gas distribution unit;
gauging the substrate's nonuniformity using a uniformity engine;
controlling gas withdrawal rate by modulating positions of one or more blades of micro shutters in an array of valves, wherein the modulation is based on the gauged nonuniformity; and
adjusting, by the system controller, currents supplied to motors coupled to said micro shutters based on input from the uniformity engine to compensate for the gauged nonuniformity.

14. The method of claim 13, further comprising synchronizing the positions of the blades using an actuator coupled to a motor through a rotational-to-linear conversion mechanism.

15. The method of claim 13, wherein the gauged nonuniformity is a result of accumulated process variations from prior processing steps on the substrate.

16. The method of claim 13, wherein the method further comprising compensating nonuniformity caused by design constraints of the process system.

17. The method of claim 13, wherein the uniformity engine includes a software module.

18. The method of claim 17, wherein the software module includes digital twins of the process system and associated processes.

19. The method of claim 13, wherein the gas distribution unit introduces gases in configurations based on either a showerhead or an injector.

20. The method of claim 13, further comprising employing a PID control with the system controller to achieve the steady state chamber pressure during the uniformity compensation process.
